(19) United States
(12) Patent Application Publication
(10) Pub. No.: US 2022/0389580 A1
(43) Pub. Date: Dec. 8, 2022

(54) NON-CONFORMAL PLASMA INDUCED ALD GAPFILL

(71) Applicant: Applied Materials, Inc., Santa Clara, CA (US)

(72) Inventors: Hanhong Chen, Milpitas, CA (US); Joseph AuBuchon, San Jose, CA (US); Zhejun Zhang, Santa Clara, CA (US)

(73) Assignee: Applied Materials, Inc., Santa Clara, CA (US)

(21) Appl. No.: 17/835,482

(22) Filed: Jun. 8, 2022

Related U.S. Application Data
(60) Provisional application No. 63/208,499, filed on Jun. 8, 2021.
(60) Provisional application No. 63/229,501, filed on Aug. 4, 2021.

(51) Int. Cl. C23C 16/455; H01J 37/32

(52) U.S. Cl. CPC C23C 16/45542; H01J 37/32752; C23C 16/45519; H01J 2237/332

(57) ABSTRACT

Embodiments of this disclosure relate to methods for depositing gapfill materials by a plasma ALD cycle including a plasma deactivation outside of and near the top of the substrate feature. Some embodiments of the disclosure relate to methods for filling reentrant features without void formation. In some embodiments, the gapfill material comprises one or more of silicon nitride and titanium nitride.

### CROSS-REFERENCE TO RELATED APPLICATIONS

This application claims priority to U.S. Provisional Application No. 63/229,501, filed Aug. 4, 2021, and U.S. Provisional Application No. 63/208,499, filed Jun. 8, 2021, the entire disclosures of which are hereby incorporated by reference herein.

### TECHNICAL FIELD

Embodiments of the disclosure generally relate to methods for depositing gapfill materials by atomic layer deposition (ALD). In particular, embodiments of disclosure relate to gapfill methods which deposit material within features to enable fill of reentrant features without seams or voids.

### BACKGROUND

Atomic layer deposition (ALD) produces conformal films. Accordingly, any use of ALD to fill substrate features with a re-entrant profile (i.e., an internal width greater than the opening width) will lead to void formation when the feature opening closes.

Various techniques have been proposed to limit film growth near feature openings in an effort to prevent premature closure and void formation. One such technique utilizes a carbon-based surface poisoning agent to slow film deposition on target surfaces. But these poisoning agents often deposit into the formed films and can cause increased impurities and adversely affect various film properties.

Accordingly, there is a need for non-conformal gapfill methods which enable fill of complex features without voids and without the use of poisoning agents.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a cross-sectional view of a substrate feature prior to processing according to one or more embodiment of the disclosure;

FIG. 2 is flowchart of a processing method according to one or more embodiment of the disclosure; and

FIG. 3 is a cross-sectional view of a substrate feature after processing according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

One or more embodiments of the disclosure are directed to ALD methods for non-conformal fill of substrate features. Some embodiments utilize a plasma treatment to de-activate portions of the substrate for subsequent ALD deposition cycles. Some embodiments of the disclosure provide methods of depositing a metal nitride film (e.g., titanium nitride (TiN) or silicon nitride (SiN)) in high aspect ratio (AR) structures with small dimensions. Some embodiments provide methods for filling reentrant features without any substantial void. Some embodiments provide methods which produce films of similar quality to traditional ALD methods.

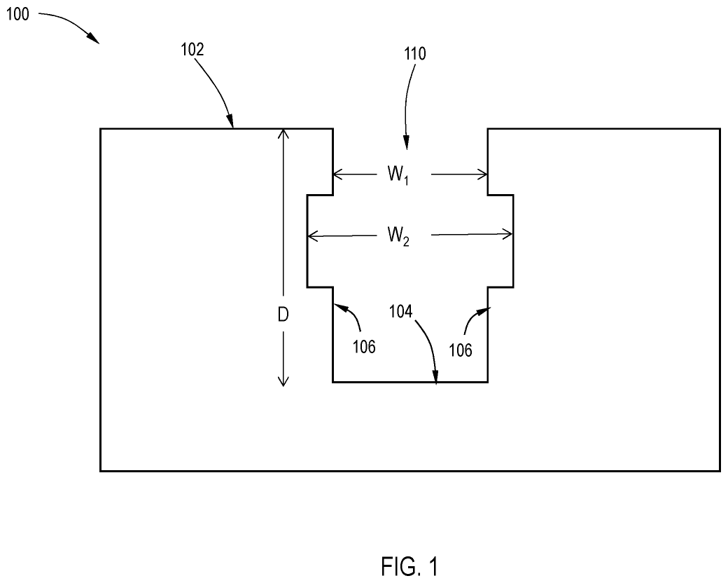

Referring to FIG. 1, some methods of this disclosure are useful for providing gapfill in substrate features 110. As shown in FIG. 1, a substrate 100 has a substrate surface 102. In some embodiments, the substrate surface 102 has at least one feature 110 formed therein. The at least one feature of some embodiments has an opening width W₁ between two sidewalls 106 and a depth D from the substrate surface 102 to a bottom 104.

In some embodiments, the feature 110 is a reentrant feature. A reentrant feature is defined by having a portion of the feature which is wider than a portion closer to the substrate surface 102. As shown in FIG. 1, W₂ is greater than W₁. Reentrant features are particularly difficult to fill with ALD gapfill material without producing voids due to premature feature closing at the narrower width before the wider width is completely filled.

In some embodiments, the at least one feature has an aspect ratio (D/W) of greater than or equal to 3:1, 5:1, 10:1, 15:1, or 20:1.

In some embodiments, the first film forms a gapfill material within the at least one feature that is without any substantial void. In this regard a “substantial” void is greater than or equal to 1 nm in width. It is noted that in some embodiments, a seam (<1 nm in width) may still be present.

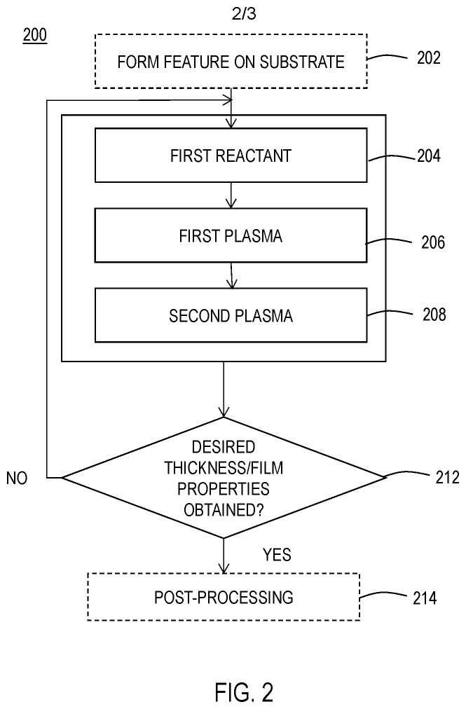

Referring to FIG. 2, in one or more embodiment, a method 200 may begin at 202 by forming the substrate feature 110. The method continues at 204 by exposing the substrate surface to a first reactant to form a first reactive species on the substrate surface and within the at least one feature.

In some embodiments, the first reactant comprises silicon. In some embodiments, the first reactant comprises or consists essentially of dichlorosilane or diiodosilane. In some embodiments, the first reactant comprises titanium. In some embodiments, the first reactant comprises or consists essentially of titanium tetrachloride (TiCl₄).

As used in this regard, a reactant which “consists essentially of” a stated compound comprises at least 95%, at least 98%, at least 99% or at least 99.5% of the stated compound on a molar basis, excluding any inert, diluent, or carrier materials (e.g., gasses, solvents).

The method continues at 206 by exposing the substrate surface to a first plasma to react with the first reactive species to form a first film on the substrate surface and within the at least one feature. Operations 204 and 206 may be understood to be similar to a typical plasma ALD process to produce a single monolayer of the first film.

The first plasma is formed from a first plasma gas. In some embodiments, the first plasma gas comprises ammonia.

The method continues at 208 by exposing the substrate surface to a second plasma to deactivate portions of the first film near the top of and outside of the at least one feature.

The second plasma is formed from a second plasma gas. In some embodiments, the second plasma gas comprises one or more of nitrogen gas (N₂) or argon. In some embodiments, the second plasma gas comprises 1-25% N₂ in argon, 5-25% N₂ in argon or 5-10% N₂ in argon.

In some embodiments, the first plasma and the second plasma are generated in the same processing region. In some embodiments, the first plasma and the second plasma are generated without an intervening pause. In some embodiments, the first plasma gas is flowed with the second plasma gas to produce the first plasma and then the first plasma gas is ceased to provide the second plasma. In some embodiments, the first plasma and the second plasma share one or more attributes. For example, in some embodiments, the first plasma and the second plasma have a power in a range of 50 W to 5000 W or in a range of 500 W to 2500 W.

The method continues at 212 by determining if a desired or predetermined thickness of the first film has been formed. If it has, the method 200 continues to 214 for optional post processing. If not, the method 200 returns to 204 for repetition of operations 204, 206 and 208.

The method 200 may be performed at any suitable temperature and/or pressure. In some embodiments, the method is performed at a chamber pressure in a range of 0.5 Torr to 20 Torr, in a range of 0.5 Torr to 5 Torr or in a range of 0.5 Torr to 2 Torr.

The resulting deposition on the deactivated portions during the repeated cycle provides a lower growth rate and less film deposition than on the unaffected portions. Accordingly, in some embodiments, after repeated cycles, the thickness of the first film is greater at the bottom of than at the top of the at least one feature.

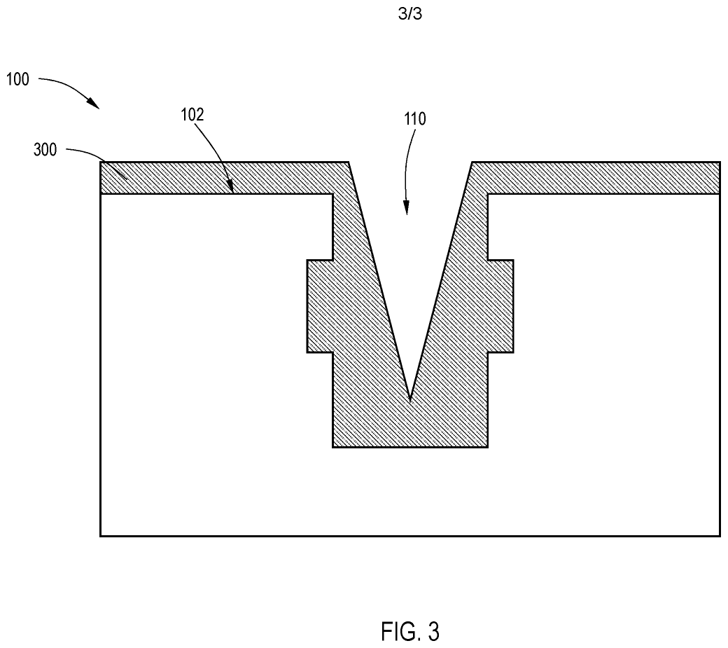

Referring to FIG. 3, the method 200 provides a lower growth rate and results in a thinner first film 300 on the deactivated portions (including the substrate surface 102 and near the opening of the at least one feature 110).

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A gapfill deposition method comprising:
exposing a substrate surface having at least one feature formed therein to a first reactant to form a first reactive species on the substrate surface and within the at least one feature;
exposing the substrate surface to a first plasma formed from a first plasma gas to react with the first reactive species to form a first film on the substrate surface and within the at least one feature and to activate the first film;
exposing the substrate surface to a second plasma formed from a second plasma gas to deactivate portions of the first film near the top of the at least one feature and outside of the at least one feature; and
repeating exposure to the first reactant, the first plasma and the second plasma to form a predetermined thickness of the first film within the at least one feature,
wherein deposition cycles on deactivated portions of the first film demonstrate lower growth rates than on portions which are not deactivated.

2. The method of claim 1, wherein the at least one feature has an aspect ration of greater than or equal to 3:1.

3. The method of claim 1, wherein the thickness of the first film is greater at the bottom of the at least one feature than at the top of the at least one feature.

4. The method of claim 1, wherein the at least one feature is a reentrant feature.

5. The method of claim 1, wherein the predetermined thickness of the first film is formed within the at least one feature substantially without void.

6. The method of claim 1, wherein the first reactant comprises silicon.

7. The method of claim 6, wherein the first reactant consists essentially of dichlorosilane.

8. The method of claim 6, wherein the first reactant consists essentially of diiodosilane.

9. The method of claim 1, wherein the first reactant comprises titanium.

10. The method of claim 9, wherein the first reactant consists essentially of titanium tetrachloride.

11. The method of claim 1, wherein the first plasma gas comprises one or more of nitrogen, ammonia, or argon.

12. The method of claim 11, wherein the first plasma gas comprises ammonia.

13. The method of claim 1, wherein the second plasma gas comprises one or more of nitrogen gas (N₂) or argon.

14. The method of claim 13, wherein the second plasma gas comprises nitrogen gas (N₂).

15. The method of claim 13, wherein the second plasma gas comprises 1-25% N₂ in argon.

16. The method of claim 1, wherein the first plasma and the second plasma are generated within the same processing region.

17. The method of claim 12, wherein ammonia from the first plasma gas is mixed into the second plasma gas.

18. The method of claim 1, wherein the first plasma and the second plasma have a power in a range of 500 W to 5000 W.

19. The method of claim 1, wherein the method is performed at a pressure in a range of 0.5 to 20 Torr.

20. A gapfill deposition method comprising:
exposing a substrate surface in a first process region to a first reactant to form a first reactive species on the substrate surface, the substrate surface having at least one feature formed therein;
moving the substrate surface through a gas curtain to a second process region;
exposing the substrate surface to a first plasma in the second process region to react with the first reactive species, form a nitride film on the substrate surface and within the at least one feature, and activate the nitride film, the first plasma formed from ammonia and a second plasma gas; and
exposing the substrate surface to a second plasma in the second process region to deactivate portions of the nitride film near the top of and outside of the at least one feature;
moving the substrate surface through a gas curtain to the first process region; and
repeating exposure in the first process region, moving the substrate surface, exposure in the second process region and moving the substrate to form a predetermined thickness of the nitride film within the at least one feature,
wherein subsequent deposition cycles demonstrate lower growth rates of the nitride film on deactivated portions of the nitride film.
